(19) United States
(12) Patent Application Publication
(10) Pub. No.: US 2011/0181271 A1
(43) Pub. Date: Jul. 28, 2011

(54) PEAKING CIRCUIT, PEAKING CIRCUIT CONTROL METHOD, WAVEFORM MEASUREMENT APPARATUS, AND INFORMATION PROCESSING APPARATUS

(76) Inventors: Norio CHUJO, Tokyo (JP); Takehito Kamimura, Tokyo (JP)

(21) Appl. No.: 13/014,130

(22) Filed: Jan. 26, 2011

(30) Foreign Application Priority Data
Jan. 26, 2010 (JP) 2010-014343

(51) Int. Cl. G01R 19/00; H03F 1/00; H03F 3/45; H03G 3/00; G06G 7/14

(52) U.S. Cl. 324/123 C; 330/291; 330/260; 330/278; 327/361

(57) ABSTRACT

A peaking circuit according to the present invention includes amplifiers connected in multiple stages and feedback circuits for feedback to an input from two or more output points with different gains as seen from the input. The peaking circuit is configured to be able to change an amount of feedback of the feedback circuits.

### CLAIM OF PRIORITY

The present application claims priority from Japanese patent application JP 2010-014343 filed on Jan. 26, 2010, the content of, which is hereby incorporated by reference into this application.

### BACKGROUND OF THE INVENTION

1. Field of the Invention

The present invention relates to a peaking circuit, a control method of the peaking circuit, a waveform measurement apparatus using the peaking circuit, and an information processing apparatus using the peaking circuit.

2. Background Art

The operation speed of electronic circuits is improving year after year, and research and development are actively conducted to realize faster electronic circuits. The faster electronic circuits are advantageous in that a process that required a significantly long time in the past can be executed in a short time, a large amount of information can be transmitted in a short time, and a measurement that could not be performed in the past can be performed by an improved resolution.

To realize faster electronic circuits, signal transmissions between LSI (Large Scale Integration) internal circuits that are constituent elements of the electronic circuits, between LSIs, between printed circuit boards, between apparatuses, between cases, etc., need to be speeded up. However, the signal waveform may be distorted by capacitance attached to the pad of the package, loss in the signal transmission line of the printed circuit board, etc. As a result, an error of an analog signal may be large, or there may be an error in the data of a digital signal.

In A 14 mW 6.25 Gb/s Transceiver in 90 nm CMOS for Serial Chip-to-Chip Communications: J. Poulton et al., ISSCC2007 p. 440-441, arrangement of capacitance on part of amplifiers is described as a technique for equalizing the signal waveform. In 10-Gb/s Limiting Amplifier and Laser Modulator Driver in 0.18-μm CMOS Technology: S. Galal et al., IEEE JOURNAL OF SOLID-STATE CIRCUITS, VOL. 38, NO. 12, DECEMBER 2003, p. 2138-2146, setting of a high-order transfer function by feedback is described. The documents are designed to set the gain of a high frequency area higher than the gain of a low frequency area based on the configurations described above. The circuits described in the documents are configured to change the difference (amount of peaking) between the gain of the low frequency area and the gain of the high-frequency area.

### SUMMARY OF THE INVENTION

In the technique described in A 14 mW 6.25 Gb/s Transceiver in 90 nm CMOS for Serial Chip-to-Chip Communications: J. Poulton et al., ISSCC2007 p. 440-441, the resistance of a resistor that determines the gain is increased to reduce the gain of the low frequency area to increase the difference between the gain of the low frequency area and the gain of the high frequency area. The resistance of the resistor that determines the gain is reduced to increase the gain of the low frequency area to reduce the difference between the gain of the low frequency area and the gain of the high frequency area. Therefore, the gain of the low frequency area is also changed to change the amount of peaking.

It is desirable to change the gain of the high frequency area in terms of eliminating the distortion of the signal waveform. However, the gain of the low frequency area is changed at the same time in A 14 mW 6.25 Gb/s Transceiver in 90 nm CMOS for Serial Chip-to-Chip Communications: J. Poulton et al., ISSCC2007 p. 440-441. Therefore, the elimination of the distortion of the high frequency area may change the signal value. Thus, the gain of the low frequency area changed by changing the gain of the high frequency area needs to be equalized, and the circuit configuration, etc., tends to be complicated.

Meanwhile, in the technique described in 10-Gb/s Limiting Amplifier and Laser Modulator Driver in 0.18-μm CMOS Technology: S. Galal et al., IEEE JOURNAL OF SOLID-STATE CIRCUITS, VOL. 38, NO. 12, DECEMBER 2003, p. 2138-2146, the output signal is fed back to the input to set a high-order circuit transfer function, and the gain of the high frequency area is set greater than the gain of the low frequency area. The gain of the feedback amplifier is changed to change the amount of feedback in order to change the amount of peaking.

As in A 14 mW 6.25 Gb/s Transceiver in 90 nm CMOS for Serial Chip-to-Chip Communications: J. Poulton et al., ISSCC2007 p. 440-441, the gain of the low frequency area is reduced to increase the difference between the gain of the low frequency area and the gain of the high frequency area, and the gain of the low frequency area is increased to reduce the difference between the gain of the low frequency area and the gain of the high frequency area due to the configuration described above. Therefore there is the same problem as in A 14 mW 6.25 Gb/s Transceiver in 90 nm CMOS for Serial Chip-to-Chip Communications: J. Poulton et al., ISSCC2007 p. 440-441.

The present invention provides a peaking technique, in which the influence on the gain of a low frequency area is reduced when the amount of peaking is changed.

A peaking circuit according to the present invention includes amplifiers connected in multiple stages and feedback circuits for feedback to an input from two or more output points with different gains as seen from the input. The peaking circuit is configured to be able to change an amount of feedback of the feedback circuits.

The peaking circuit according to the present invention has feedbacks from two or more output points with different gains as seen from the input. The amount of peaking obtained by one feedback is different from the amount of peaking obtained by another feedback. As a result, the amount of peaking of the entire peaking circuit is determined by a total of the amounts of peaking obtained by a plurality of feedbacks. Therefore, even if the gain of the low frequency area is reduced by a feedback, the gain of the high frequency area can be changed while compensating the reduction by another feedback.

These and other objects, features and advantages of the invention will be apparent from the following more particular description of preferred embodiments of the invention, as illustrated in the accompanying drawings.

### BRIEF DESCRIPTION OF THE DRAWINGS

FIG. 1 is a circuit diagram of a peaking circuit 10 according to a first embodiment.

FIG. 2 is a diagram showing frequency characteristics of the gain of the peaking circuit 10.

FIG. 3 is a circuit diagram of the peaking circuit 10 according to a second embodiment.

FIG. 4 is a circuit diagram of the peaking circuit 10 according to a third embodiment.

FIG. 5 is a circuit diagram of the peaking circuit 10 according to a fourth embodiment.

FIG. 6 is a configuration diagram of a waveform measurement apparatus 100 according to a fifth embodiment.

FIG. 7 is a configuration diagram of an information processing apparatus 200 according to a sixth embodiment.

FIG. 8 is a circuit diagram of an LSI 64.

FIG. 9 is a circuit diagram of a peaking circuit according to A 14 mW 6.25 Gb/s Transceiver in 90 nm CMOS for Serial Chip-to-Chip Communications: J. Poulton et al., ISSCC2007 p. 440-441.

FIG. 10 shows frequency characteristics of the peaking circuit of FIG. 9.

FIG. 11 is a circuit diagram of a peaking circuit 40 according to 10-Gb/s Limiting Amplifier and Laser Modulator Driver in 0.18-μm CMOS Technology: S. Galal et al., IEEE JOURNAL OF SOLID-STATE CIRCUITS, VOL. 38, NO. 12, DECEMBER 2003, p. 2138-2146.

### DESCRIPTION OF SYMBOLS

10: peaking circuit, 11: input terminal, 12: first amplifier, 13: second amplifier, 14: first feedback circuit, 14a and 14b: transistors, 14c: current source, 15: second feedback circuit, 15a and 15b: transistors, 15c: current source, 15d and 15e: control pins, 16: output terminal, 51: sensor, 52: preamplifier, 53: transmission line, 54: waveform measurement unit, 100: waveform measurement apparatus, 60: backplane, 62: connector, 61a, 61b, 61c, and 61d: printed circuit boards, 63 and 64: LSIs, 66a, 66b, and 66c: limit amplifiers, 68: decision feedback equalizer, 68a and 68b: offset voltages, 200: information processing apparatus.

### DETAILED DESCRIPTION OF THE PREFERRED EMBODIMENTS

### First Embodiment

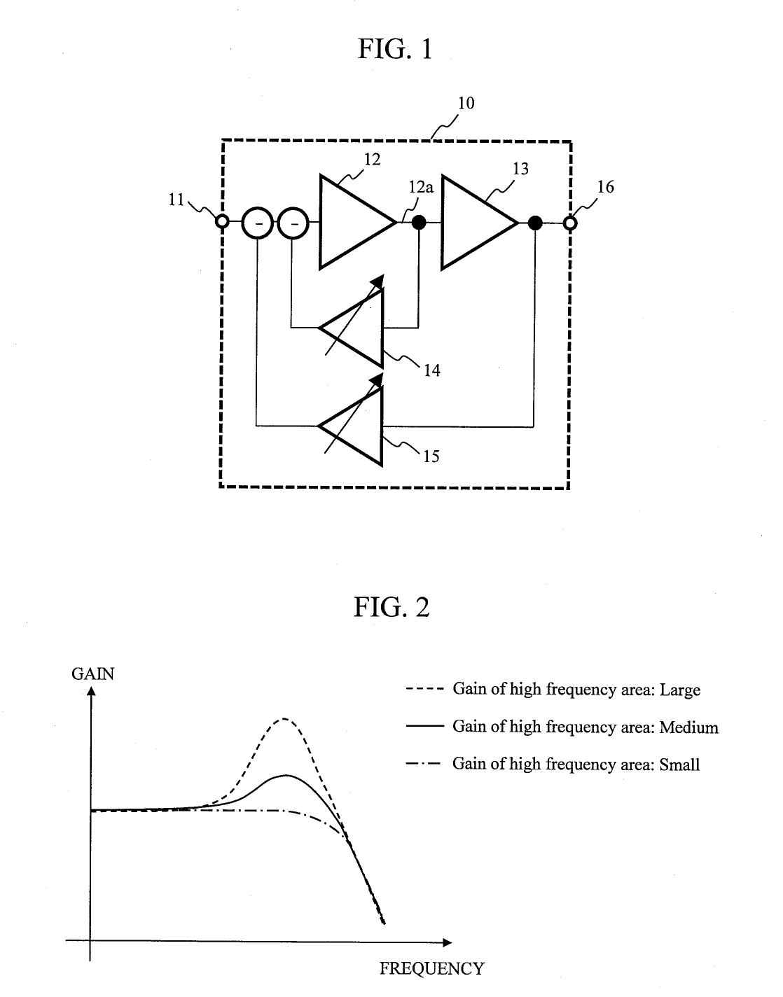

FIG. 1 is a circuit diagram of a peaking circuit 10 according to a first embodiment of the present invention. The peaking circuit 10 includes an input terminal 11, a first amplifier 12, a second amplifier 13, a first feedback circuit 14, a second feedback circuit 15, and an output terminal 16.

The input terminal 11 is a terminal which input signal to the peaking circuit 10 and the output terminal 16 is a terminal which output signals of the peaking circuit 10.

The first amplifier 12 and the second amplifier 13 form multi-stage amplifiers serially connected in multiple stages. The first amplifier 12 amplifies an input signal inputted to the input terminal 11, and the second amplifier 13 further amplifies an output of the first amplifier 12.

The first feedback circuit 14 is connected to an output terminal 12a of the first amplifier 12 to feed back an output of the first amplifier 12 to the input terminal 11. The second feedback circuit 15 is connected to an output terminal of the second amplifier 13 to feed back an output of the second amplifier 13 (it means output terminal 16) to the input terminal 11.

The circuit constituted by the first amplifier 12 and the first feedback circuit 14 includes a quadratic transfer function. The circuit constituted by the first amplifier 12, the second amplifier 13, and the second feedback circuit 15 includes a cubic transfer function, because one more stage of amplifier is added.

The difference (amount of peaking) between the gain in a low frequency area and the gain in a high frequency area of the peaking circuit 10 is determined by the gain of the first feedback circuit 14 and the gain of the second feedback circuit 15.

The gain in the low frequency area of the peaking circuit 10 is expressed by the following Formula 1. The low frequency area denotes a frequency band that realizes Formula 1. In the actual control, for example, a frequency area below a predetermined frequency is handled as the low frequency area, and a frequency area above the predetermined frequency is handled as the high frequency area.

$$\begin{matrix}[ Expression 1 ] & \\ {V}_{out} = \frac{{G}_{a}^{2}}{1 + {G}_{a} {G}_{c} + {G}_{a}^{2} {G}_{d}} {V}_{in} & ( Formula 1 )\end{matrix}$$

### Where

Ga: gains of the amplifiers 12 and 13
Gc: gain of the first feedback circuit 14
Gd: gain of the second feedback circuit 15

It is assumed that the gain Gc of the first feedback circuit 14 has changed to GcAx and that the gain Gd of the second feedback circuit 15 has changed to GdAy. In this case, the following Formula 2 can be set to maintain the gain in the low frequency area of the peaking circuit 10 to the gain expressed in Formula 1.

$$\begin{matrix}[ Expression 2 ] & \\ Δ x = 1 - \frac{{G}_{a} {G}_{d}}{{G}_{c}} ( Δ y - 1 ) \\ When {G}_{c} = {G}_{a} {G}_{d} , \\ Δ x = - Δ y & ( Formula 2 )\end{matrix}$$

Formula 2 indicates that the relationship of Formula 1 is mostly realized if the change in the gain Gc of the first feedback circuit 14 and the change in the gain Gd of the second feedback circuit 15 are substantially inverted.

The circuit constituted by the first amplifier 12, the second amplifier 13, and the second feedback circuit 15 has a cubic transfer function. Therefore, a greater amount of peaking can be obtained, compared to the circuit that includes a quadratic transfer function and that is constituted by the first amplifier 12 and the first feedback circuit 14.

The difference (amount of peaking) between the gain of the low frequency area and the gain of the high frequency area can be changed by using the characteristics described above to change the contribution rate of the circuit including the quadric transfer function and the contribution rate of the circuit including the cubic transfer function to the gain of the peaking circuit 10. More specifically, the amount of peaking of the peaking circuit 10 can be adjusted by changing the gain Gc of the first feedback circuit 14 and the gain Gd of the second feedback circuit 15.

The relationship of Formula 1 can be maintained in the low frequency area by changing the gain Gc of the first feedback circuit 14 and the gain Gd of the second feedback circuit 15 to realize Formula 2 upon the adjustment of the amount of peaking of the peaking circuit 10.

FIG. 2 is a diagram showing frequency characteristics of the gain of the peaking circuit 10. The gain of the high frequency area can be changed without reducing the gain of the low frequency area as shown in FIG. 2 if the gain Gc of the first feedback circuit 14 and the gain Gd of the second feedback circuit 15 are changed to realize Formula 2.

Although the use of the feedback circuit including the quadratic transfer function and the feedback circuit including the cubic transfer function has been described, a feedback circuit including a higher-order transfer function may be further connected to a latter stage of the second amplifier 13. More specifically, an additional amplifier may be connected to the latter stage of the second amplifier 13, and an additional feedback circuit may feed back the output to the input terminal 11. Although the first feedback circuit 14 and the second feedback circuit 15 are configured by one stage each, the circuits may be configured in multiple stages. The same applies to the following embodiments.

As described, the peaking circuit 10 according to the present first embodiment has feedback of returning to the input terminal 11 from two output terminals 12a and 16 with different gains as seen from the input terminal 11. Even if the gain of the low frequency area is reduced by the first feedback circuit 14, the gain of the high frequency area can be varied while compensating the gain of the low frequency area by the second feedback circuit 15.

### Second Embodiment

A specific example of configuration of the peaking circuit 10 described in the first embodiment will be described in a second embodiment of the present invention. Although the overall configuration of the peaking circuit 10 is mostly the same as in FIG. 1 described in the first embodiment, it is different in that configurations of the amplifiers are more specifically embodied.

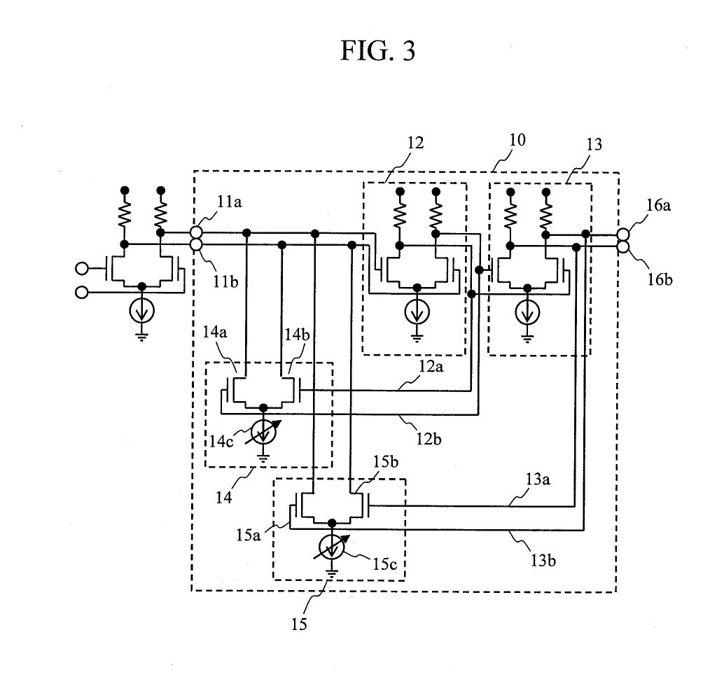

FIG. 3 is a circuit diagram of the peaking circuit 10 according to the present second embodiment. In the present second embodiment, differential amplifiers are used to constitute the first amplifier 12, the second amplifier 13, the first feedback circuit 14, and the second feedback circuit 15.

Each differential amplifier includes two transistors, receives an input signal corresponding to each transistor, and outputs an output signal corresponding to each transistor. Each differential amplifier includes a current source and is capable of changing the gain by changing the amount of current of the current source.

The first feedback circuit 14 is connected to output terminals 12a and 12b of the first amplifier 12 to feed back an output of the first amplifier 12 to the input terminals 11a and 11b. The second feedback circuit 15 is connected to output terminals 13a and 13b of the second amplifier 13 to feed back an output of the second amplifier 13 to the input terminals 11a and 11b.

As in the first embodiment, the gain of the first feedback circuit 14 and the gain of the second feedback circuit 15 can be changed to change the amount of peaking of the peaking circuit 10 in the present second embodiment. Specifically, the following methods can be considered.

### (Method 1 for Changing Gain)

The amount of current of a current source 14c included in the first feedback circuit 14 is adjusted to set the gain Gc to a desired value. The amount of current of a current source 15c included in the second feedback circuit 15 is adjusted to set the gain Gd to a desired value.

### (Method 2 for Changing Gain)

A resistor is connected to a source of at least one of transistors 14a and 14b included in the first feedback circuit 14 to adjust the amount of electric current to set the gain Gc to a desired value. A resistor is connected to a source of at least one of transistors 15a and 15b included in the second feedback circuit 15 to adjust the amount of electric current to set the gain Gd to a desired value.

### (Method 3 for Changing Gain)

The size of at least one of the transistors 14a and 14b is changed to adjust the amount of electric current to set the gain Gc to a desired value. The size of at least one of the transistors 15a and 15b is changed to adjust the amount of electric current to set the gain Gd to a desired value.

A specific example of configuration of the peaking circuit 10 described in the first embodiment has been described in the present second embodiment. The same advantages as in the first embodiment can be attained in the present second embodiment by changing the gain of the first feedback circuit 14 and the gain of the second feedback circuit 15 to satisfy Formula 2.

### Third Embodiment

Another example of configuration of the peaking circuit 10 described in the first and second embodiments will be described in a third embodiment of the present invention. Although the overall configuration of the peaking circuit 10 is mostly the same as in the first and second embodiments, the configurations of the amplifiers are different in the third embodiment.

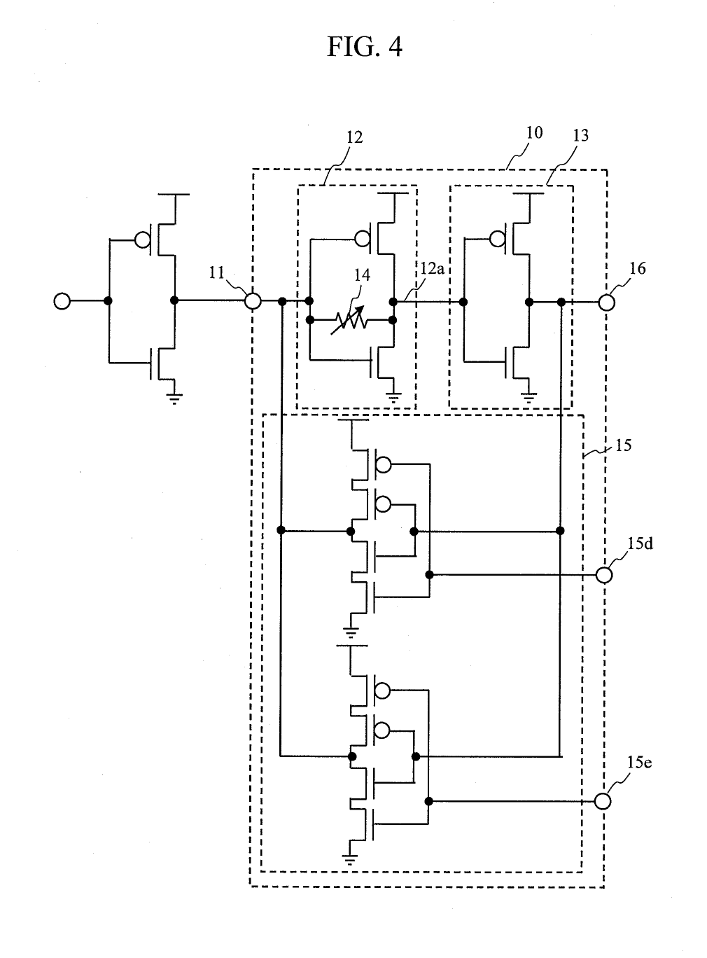

FIG. 4 is a circuit diagram of the peaking circuit 10 according to the present third embodiment. The configurations of the circuits will be described.

CMOS (Complementary Metal Oxide Semiconductor) inverter circuits are used to constitute the first amplifier 12 and the second amplifier 13 in the present third embodiment. A variable resistor is used to constitute the first feedback circuit 14.

The second feedback circuit 15 includes two feedback circuits inside. The gain of the entire second feedback circuit 15 can be changed by switching on/off the internal feedback circuits through control pins 15d and 15e.

As in the first and second embodiments, the gain of the first feedback circuit 14 and the gain of the second feedback circuit 15 can be changed to change the amount of peaking of the peaking circuit 10 in the present third embodiment.

Specifically, the resistance of the variable resistor constituting the first feedback circuit 14 is changed to adjust the amount of feedback to the input terminal 11. The gain of the second feedback circuit 15 is changed by switching on/off the internal feedback circuits through the control pins 15d and 15e.

Another example of configuration of the peaking circuit 10 described in the second embodiment has been described in the present third embodiment. The number of feedback circuits included in the second feedback circuit 15 may be three or more. The amount of peaking of the peaking circuit 10 can be more precisely controlled by increasing the number of feedback circuits.

Although the variable resistor is used to constitute the first feedback circuit 14 in the present third embodiment, the other feedback circuit 15 may be constituted by the variable resistor. The same applies when three or more stages of amplifiers are arranged.

### Fourth Embodiment

In a fourth embodiment of the present invention, a simplified configuration of the second feedback circuit 15 described in FIG. 4 of the third embodiment will be described. The other configurations are the same as in the third embodiment.

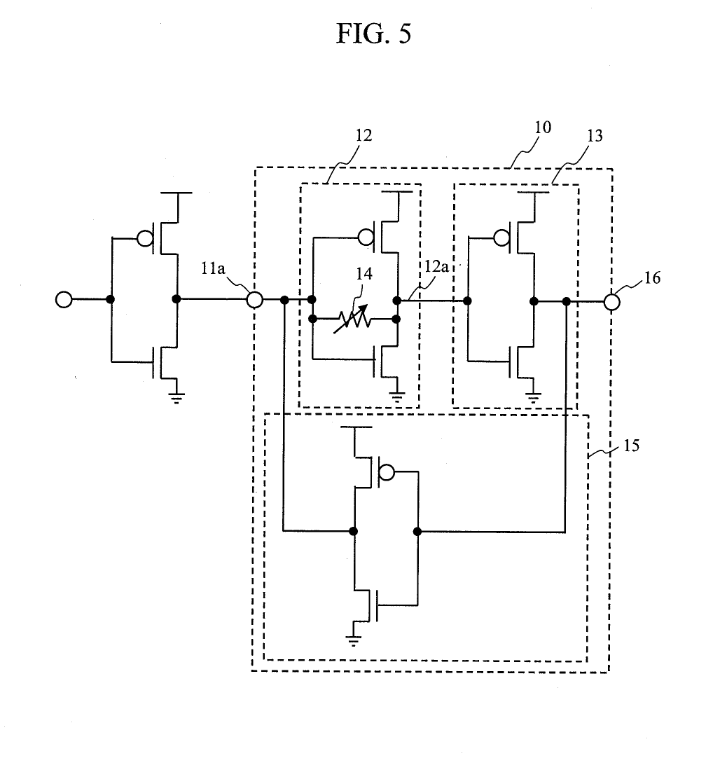

FIG. 5 is a circuit diagram of the peaking circuit 10 according to the present fourth embodiment. Differences from FIG. 4 of the third embodiment will be described.

If the variable resistor included in the first feedback circuit 14 is reduced to increase the amount of feedback of the first feedback circuit 14 in FIG. 4 of the third embodiment, the input resistance at the input terminal 11 of the peaking circuit 10 is reduced, and accordingly, the amount of feedback of the second feedback circuit 15 is naturally reduced. In other words, the amount of feedback of the second feedback circuit 15 is naturally changed only by changing the amount of feedback of the variable resistor. This can be used to attain substantially the same advantages as in the third embodiment just by changing the resistance of the variable resistor.

Therefore, the configuration of the second feedback circuit 15 in the present fourth embodiment is simpler than the configuration of the second feedback circuit 15 in FIG. 4 of the third embodiment. The characteristics of the peaking circuit 10 in the present fourth embodiment will be described.

An input resistance rin of the first amplifier 12 can be expressed by Formula 3.

$$\begin{matrix}[ Expression 3 ] & \\ {r}_{in} = \frac{R}{1 + {G}_{e}} & ( Formula 3 )\end{matrix}$$

### Where

R: resistance of variable resistor included in the first feedback circuit 14
Ge: gain of the first amplifier 12 when resistance of variable resistor is large enough (can be assumed infinite)

The gain of the second feedback circuit 15 is taken into consideration, and an amount of feedback GFB of the second feedback circuit 15 can be expressed by Formula 4.

$$\begin{matrix}[ Expression 4 ] & \\ {G}_{FB} = \frac{{r}_{in} // {r}_{oa}}{{r}_{ob} + {r}_{in} // {r}_{oa}} {G}_{f} & ( Formula 4 )\end{matrix}$$

### Where

Gf: gain of the second feedback circuit 15
roa: output resistance of the first amplifier 12
rob: output resistance of the second feedback circuit 15

The following Formula 5 is also realized.

$$\begin{matrix}[ Expression 5 ] & \\ When {r}_{in} << {r}_{oa} , {r}_{in} << {r}_{ob} , \\ {G}_{FB} = \frac{{r}_{in}}{{r}_{ob}} {G}_{f} ∝ R & ( Formula 5 )\end{matrix}$$

If a resistance R of the variable resistor is reduced when the condition expressed by Formula 5 is satisfied, the amount of feedback GFB of the second feedback circuit 15 is reduced in proportion to the resistance R of the variable resistor.

The reduction of the resistance R of the variable resistor denotes an increase in the gain Gc of the first feedback circuit 14. In this case, the gain Gd of the second feedback circuit 15 is reduced as described above. Therefore, the change in the gain Gc of the first feedback circuit 14 and the change in the gain Gd of the second feedback circuit 15 are substantially inverted, and the condition expressed by Formula 2 described in the first embodiment is mostly satisfied. Therefore, in the present fourth embodiment, the gain of the low frequency area is mostly not changed even if the amount of peaking is changed.

As described, according to the present fourth embodiment, substantially the same advantages as in the third embodiment can be attained by simplifying the configuration of the second feedback circuit 15 when the condition expressed by Formula 5 is satisfied.

### Fifth Embodiment

An apparatus that uses the peaking circuit 10 described in the first to fourth embodiments to measure a waveform will be described in an embodiment of the present invention.

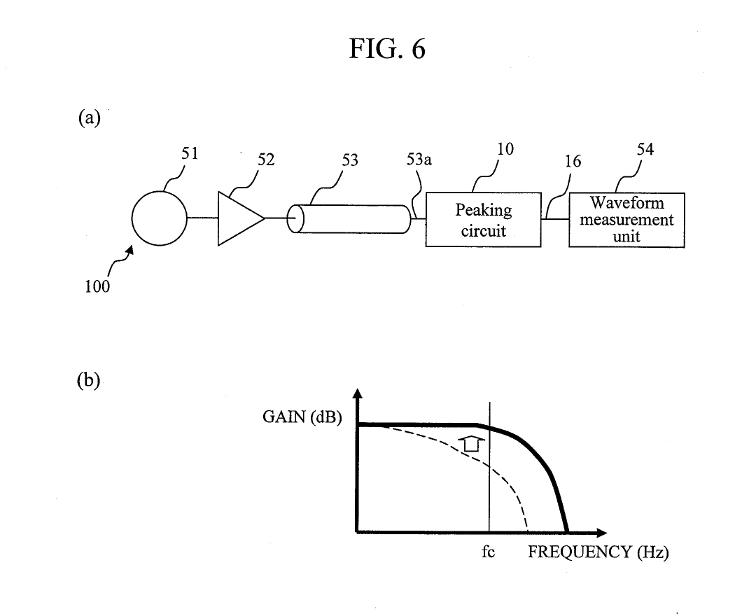

FIG. 6 is a configuration diagram of a waveform measurement apparatus 100 according to the present fifth embodiment. The waveform measurement apparatus 100 includes a sensor 51, a preamplifier 52, a transmission path 53, the peaking circuit 10, and a waveform measurement unit 54. The peaking circuit 10 is configured as described in the first to fourth embodiments.

The sensor 51 measures a measurement target and outputs a signal showing the measurement result. There are conductor loss and dielectric loss in the transmission path 53, and the loss of higher frequency components of signal is larger in an output unit 53a of the transmission path 53. Therefore, the waveform is distorted. The peaking circuit 10 reshapes the frequency characteristics up to a signal band fc into a flat shape and provides outputs to the waveform measurement unit 54 according to the frequency characteristics.

The loss in the transmission path 53 varies depending on the location of the sensor or the configuration of the apparatus. Therefore, the peaking circuit 10 needs to change the difference (amount of peaking) between the gains of the low frequency area and the high frequency area in accordance with the loss of the transmission path 53. In this case, the signal output amplitude of the output terminal 16 of the peaking circuit changes when the gain of the low frequency area is changed by changing the amount of peaking. Therefore, the methods described in the first to fourth embodiments are used to adjust the gain of the peaking circuit 10 without changing the gain of the low frequency area.

According to the present fifth embodiment, the change in the gain of the low frequency area can be reduced even if the loss of the high frequency area in the transmission path 53 is equalized. Therefore, unlike the conventional techniques, a variable gain circuit, etc., that further equalizes the change in the gain of the low frequency area is not required, and the fifth embodiment is advantageous in terms of cost, power consumption, ease of control, etc.

Measurement conditions may be predetermined in a normal measurement environment. Under such an environment, the amount of peaking of the peaking circuit 10 does not have to be variable if the gain of the peaking circuit 10 is adjusted in advance in accordance with the measurement environment. On the other hand, it is suitable to use the peaking circuit 10 according to the present invention to handle the peaking circuit 10 in an arbitrary measurement environment.

### Sixth Embodiment

An apparatus that uses the peaking circuit 10 described in the first to fourth embodiments to execute information processing will be described in a sixth embodiment of the present invention.

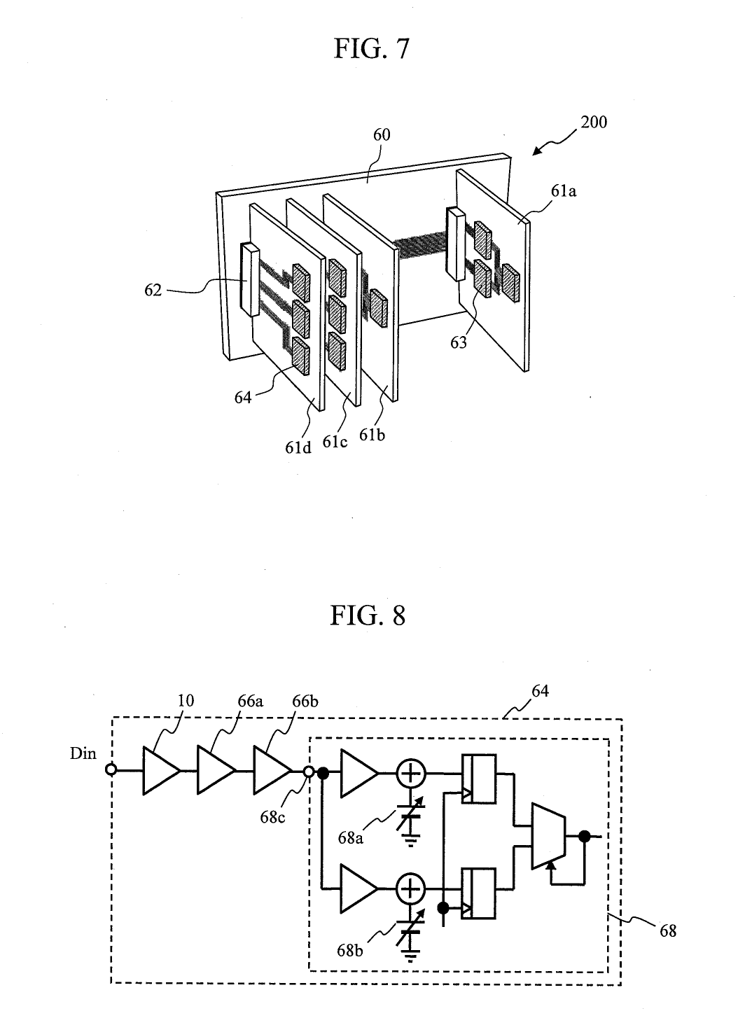

FIG. 7 is a configuration diagram of an information processing apparatus 200 according to the present sixth embodiment. The information processing apparatus 200 includes a plurality of printed circuit boards 61a, 61b, 61c, and 61d connected to a backplane 60 through a connector 62. LSIs 63 and 64 are mounted on each of the printed circuit boards 61a to 61d. The LSI 63 or 64 transmits and receives a signal to and from the LSI 63 or 64 of another board through the backplane 60. The LSIs 63 and 64 are equivalent to “arithmetic circuits” in the present sixth embodiment.

There are conductor loss and dielectric loss in the transmission line on the backplane 60 and the boards 61, and the loss is larger for higher frequency components. As a result, the quality of the waveform is degraded, and an error occurs in the data if the loss is large.

FIG. 8 is a circuit diagram of the LSI 64. A circuit diagram of the LSI 63 is the same, thus the description will not be repeated. The LSI 64 includes the peaking circuit 10 described in the first to fourth embodiments, limit amplifiers 66a, 66b, and 66c, and a feedback determination equalizer 68. The LSI 64 uses the peaking circuit 10 and the feedback determination equalizer 68 to equalize the loss in the transmission path on the backplane 60 and the boards 61 to improve the signal quality.

The length of the transmission line on the back plane 60 and the boards 61 varies depending on the connection locations of the boards 61 to the backplane 60, and the loss is also different in each board 61. Therefore, the amount of peaking of the peaking circuit 10 needs to be adjustable if the same peaking circuit 10 is used for all boards 61.

However, if the gain of the low frequency area is changed by changing the amount of peaking of the peaking circuit 10, the signal output amplitude at an input 68c of the feedback determination equalizer 68 is changed. Therefore, the LSI 64 uses a separately included control circuit, etc., to optimally adjust the amount of peaking of the peaking circuit 10 in accordance with the connection locations of the boards 61.

If the peaking circuit 10 described in the first to fourth embodiments is used, the gain of the low frequency area does not change even if the amount of peaking is changed. Therefore, a new circuit, such as a variable gain circuit, does not have to be added, and offset voltages 68a and 68b do not have to be changed. This is advantageous in terms of cost, power consumption, ease of control, etc.

Although the present fifth embodiment has described that there is a difference in the length of the transmission path depending on the arrangement locations of the boards 61 relative to the backplane 60, the same problem is generated by the arrangement locations of the LSIs 63 and 64 on the boards 61. The peaking circuit 10 described in the first to fourth embodiments is also used in this case, and the gain of the high frequency area can be increased by the same method.

### Embodiments of Conventional Techniques

Embodiments as references for describing the problems of the conventional techniques will be described.

### First Embodiment of Conventional Techniques

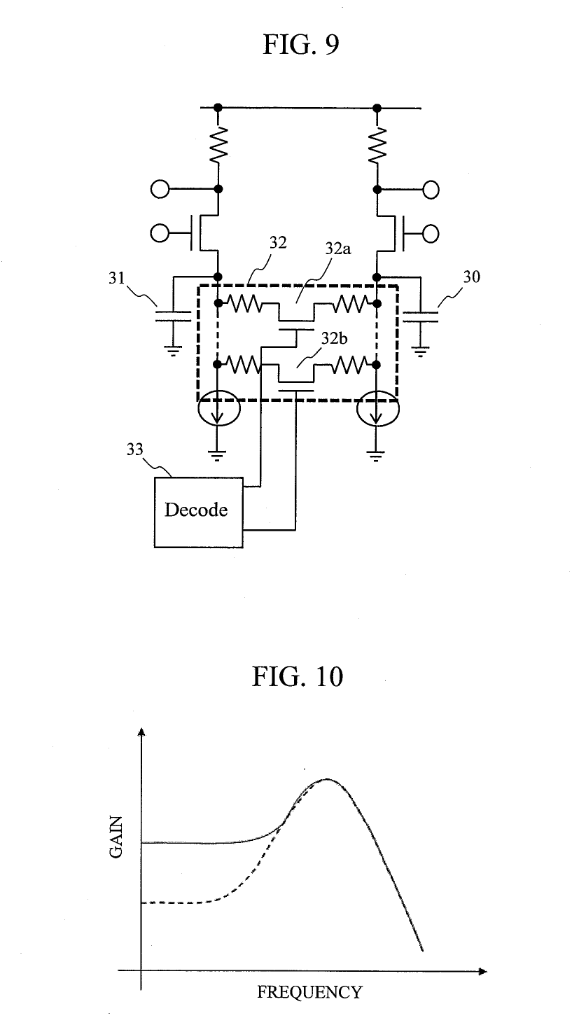

FIG. 9 is a circuit diagram of a peaking circuit in A 14 mW 6.25 Gb/s Transceiver in 90 nm CMOS for Serial Chip-to-Chip Communications: J. Poulton et al., ISSCC2007 p. 440-441. Capacitances 30 and 31 arranged in an amplifier are used to bypass a resistor 32 that determines the gain in A 14 mW 6.25 Gb/s Transceiver in 90 nm CMOS for Serial Chip-to-Chip Communications: J. Poulton et al., ISSCC2007 p. 440-441. In this way, the gain of the high frequency area is set higher than the gain of the low frequency area.

In a peaking amplifier of A 14 mW 6.25 Gb/s Transceiver in 90 nm CMOS for Serial Chip-to-Chip Communications: J. Poulton et al., ISSCC2007 p. 440-441, a decoder 33 turns on/off MOS transistors 32a and 32b to change the resistance of the resistor 32 that determines the gain in order to change the difference (amount of peaking) between the gain of the low frequency area and the gain of the high frequency area.

For example, only the MOS transistor 32a is turned on to increase the resistance of the resistor 32 that determines the gain in order to increase the difference (amount of peaking) between the gains of the low frequency area and the high frequency area. Both the MOS transistors 32a and 32b are turned on to reduce the resistance of the resistor 32 that determines the gain to reduce the difference (amount of peaking) between the gains of the low frequency area and the high frequency area.

FIG. 10 shows frequency characteristics of the peaking circuit of FIG. 9. In the circuit of FIG. 9, the gain of the low frequency area is reduced when the difference (amount of peaking) between the gains of the low frequency area and the high frequency area is increased, and the gain of the low frequency area increases when the difference (amount of peaking) between the gains of the low frequency area and the high frequency area is reduced.

### Second Embodiment of Conventional Techniques

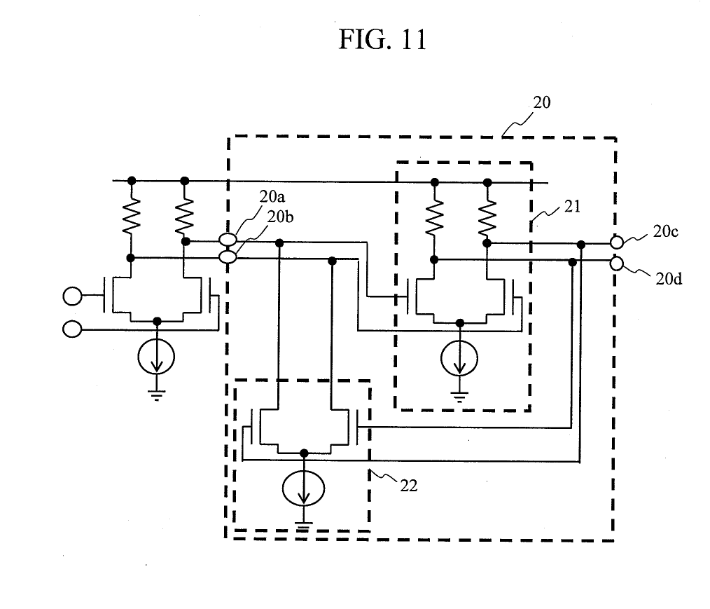

FIG. 11 is a circuit diagram of a peaking circuit 40 in 10-Gb/s Limiting Amplifier and Laser Modulator Driver in 0.18-μm CMOS Technology: S. Galal et al., IEEE JOURNAL OF SOLID-STATE CIRCUITS, VOL. 38, NO. 12, DECEMBER 2003, p. 2138-2146. In the peaking circuit 40, a feedback circuit 42 is configured to feed back an output of an amplifier 41 to the input. Signals are fed back to inputs 40a and 40b from outputs 40c and 40d of the peaking circuit 40.

The gain of the feedback circuit 42 is changed to change the amount of feedback in order to change the difference (amount of peaking) between the gains of the low frequency area and the high frequency area. Therefore, as in A 14 mW 6.25 Gb/s Transceiver in 90 nm CMOS for Serial Chip-to-Chip Communications: J. Poulton et al., ISSCC2007 p. 440-441, the gain of the low frequency area is reduced when the difference (amount of peaking) between the gains of the low frequency area and the high frequency area is increased, and the gain of the low frequency area increases when the difference (amount of peaking) between the gains of the low frequency area and the high frequency area is reduced.

The invention may be embodied in other specific forms without departing from the spirit or essential characteristics thereof. The present embodiment is therefore to be considered in all respects as illustrative and not restrictive, the scope of the invention being indicated by the appended claims rather than by the foregoing description and all changes which come within the meaning and range of equivalency of the claims are therefore intended to be embraced therein.

What is claimed is:

1. A peaking circuit with peaking characteristics, the peaking circuit comprising:
a multi-stage amplifier including amplifiers connected in multiple stages; and
two or more feedback circuits that feed back signal outputs of the amplifiers to an input of the peaking circuit, wherein
the feedback circuits are configured to be able to change an amount of feedback, and
the feedback circuits are arranged for two or more output points in the multi-stage amplifier, the output points having different gains as seen from the input of the peaking circuit.

2. The peaking circuit according to claim 1, wherein
differential amplifiers are used to constitute the amplifiers and the feedback circuits.

3. The peaking circuit according to claim 1, wherein
variable resistors are used to constitute one or more of the feedback circuits.

4. The peaking circuit according to claim 3, wherein
CMOS amplifiers are used to constitute the amplifiers, and
the CMOS amplifiers are used to constitute feedback circuits that do not use the variable resistors among the feedback circuits.

5. A method of controlling an amount of peaking of the peaking circuit according to claim 1, the method comprising
a step of changing gains of one or more of the feedback circuits to change the amount of peaking in a frequency area higher than a predetermined frequency, wherein
in the step, the gains of the feedback circuits are changed so that the amount of peaking in a frequency area lower than the predetermined frequency is not changed even if the amount of peaking in the high frequency area is changed.

6. A method of controlling an amount of peaking of the peaking circuit according to claim 3, the method comprising
a step of changing the resistances of the variable resistors to change the amount of peaking in a frequency area higher than a predetermined frequency, wherein
in the step, the resistances are changed so that the amount of peaking in a frequency area lower than the predetermined frequency is not changed even if the amount of peaking in the high frequency area is changed.

7. A waveform measurement apparatus comprising:
the peaking circuit according to claim 1; and
a waveform measurement unit that measures a waveform in which peaking is amplified by the peaking circuit.

8. An information processing apparatus comprising:
an arithmetic circuit comprising the peaking circuit according to claim 1; and
a circuit board including the arithmetic circuit.

9. The information processing apparatus according to claim 8, wherein the arithmetic circuit executes the peaking circuit control method of claim 5 to control the amount of peaking of the peaking circuit.
